(19) United States
(12) Patent Application Publication
(10) Pub. No.: US 2024/0355626 A1
(43) Pub. Date: Oct. 24, 2024

(54) METHOD FOR CONTROLLING RESISTIVITY AND CRYSTALLINITY OF LOW-RESISTANCE MATERIAL THROUGH PVD

(71) Applicant: ULVAC, INC., Chigasaki-shi (JP)

(72) Inventors: Chang Min SHIM, Pyeongtaek-si (KR); Do Hyun OH, Pyeongtaek-si (KR); Hang KANG, Pyeongtaek-si (KR); Byeong Hwa JEONG, Hwaseong-si (KR); Takahiro NAKAYAMA, Chigasaki (JP); Tomohiro SAITOU, Chigasaki (JP)

(73) Assignee: ULVAC, INC., Chigasaki-shi (JP)

(21) Appl. No.: 18/574,093

(22) PCT Filed: Jun. 8, 2022
(86) PCT No.: PCT/KR2022/008042

§ 371 Date: Dec. 26, 2023

(30) Foreign Application Priority Data
Jun. 30, 2021 (KR) 10-2021-0085404

(51) Int. Cl. H01L 21/285; C23C 14/06; C23C 14/16; C23C 14/34; C23C 14/35

(52) U.S. Cl. CPC H01L 21/2855; C23C 14/0641; C23C 14/16; C23C 14/3435; C23C 14/35; H01L 21/28568

(57) ABSTRACT

The present invention relates to a low-resistance material film formation method for forming a film on a semiconductor substrate by using physical vapor deposition (PVD), comprising the steps of: a) forming a barrier layer on a SiO₂ wafer by using low-temperature magnetron sputtering at a pressure of 1-40 Pa; b) modifying, after formation of the barrier layer, the surface of the barrier layer by applying RF bias in an Ar gas atmosphere without applying DC power; and c) layering a low-resistance material on the barrier layer by using magnetron sputtering, wherein the low-resistance material is at least one selected from the group consisting of tungsten (W), ruthenium (Ru), molybdenum (Mo), cobalt (Co) and rhodium (Rh).

### TECHNICAL FIELD

The present disclosure relates to a method of controlling resistivity and crystallinity of a semiconductor substrate film using physical vapor deposition (PVD) and, more particularly, to a method of controlling resistivity and crystallinity of a semiconductor substrate film including steps of depositing a barrier layer including titanium nitride (TiN), tantalum nitride (TaN), or silicon nitride (SiNₓ, where x>0) on a SiO₂ wafer, using PVD; and performing an after-bias treatment and then depositing tungsten (W), ruthenium (Ru), cobalt (Co), rhodium (Rh), or molybdenum (Mo), or to a method of forming a film with a low-resistance material (e.g., W, Ru, Mo, Co, Rh, etc.).

### BACKGROUND ART

The finer size of semiconductor devices has accelerated the reviews on the use of materials with low resistivity such as tungsten (W), molybdenum (Mo), cobalt (Co), rhodium (Rh), and ruthenium (Ru) for next generation wiring structures, among which Ru is one of the materials for which active research and development is conducted as an alternative material for Cu. Ru, which is used by being deposited along with TiN (TaN, SiNₓ) as an adhesion and barrier layer, may contribute to the orientation of TiN when it is deposited on a lower layer (TiN), and may accordingly generate a void and degrade crystallinity.

To solve such an issue, according to the present disclosure, a physical vapor deposition (PVD)-based low-temperature (100° C. or less) high-pressure process was performed on a lower film TiN to deposit an amorphous-like film, and an after-bias treatment was continuously performed, thereby the roughness of TiN was improved. It was verified that depositing Ru on the TiN layer formed by the foregoing process may improve the void and reduce the resistivity.

### Prior Art Document (Patent Document)

(1) Korea Patent Publication No. 10-2019-0051082 (2019 May 14)

### DISCLOSURE OF INVENTION

### Technical Goals

For TiN, chemical vapor deposition (CVD) and atomic layer deposition (ALD) are used to improve film quality such as film density, resistance, and the like, and physical vapor deposition (PVD) is used to deposit TiN through a radio frequency (RF) bias application and high-temperature film formation process. However, the present disclosure is provided to intentionally obtain an amorphous-like (high-resistivity) film quality through PVD for a TiN layer, thereby allowing the amorphous TiN film to increase the grain size of Ru and improve the crystallinity.

In addition, the present disclosure is provided to improve the roughness of TiN, suppress the void generation of Ru, and improve the crystallinity by applying an after-bias treatment or bombardment to TiN of the amorphous-like film before forming a Ru film, and obtain a low-resistivity Ru film by forming the film on the TiN layer.

However, technical goals obtainable from the present disclosure are not limited to the goals described above, and other goals that are not described above may also be clearly understood from the following description by one of ordinary skill in the art to which the present disclosure pertains.

### Technical Solutions

According to an embodiment of the present disclosure, there is provided a method of forming a film of a low-resistance material on a semiconductor substrate using physical vapor deposition (PVD), the method including:
step (a) of depositing a barrier layer on a SiO₂ wafer using low-temperature (100° C. or less) magnetron sputtering at a pressure of 1 to 40 pascal (Pa);
step (b) of modifying, after the barrier layer is deposited, the surface of the barrier layer by applying a radio frequency (RF) bias in an argon (Ar) gas atmosphere without applying direct current (DC) power; and
step (c) of depositing a low-resistance material on the barrier layer using magnetron sputtering,
wherein the low-resistance material is at least one selected from the group consisting of tungsten (W), ruthenium (Ru), molybdenum (Mo), cobalt (Co), and rhodium (Rh).

The barrier layer may be at least one selected from the group consisting of titanium nitride (TiN), tantalum nitride (TaN), and silicon nitride (SiNₓ, where x>0).

Step (c) may include forming a nucleation layer (seed layer) of the low-resistance material and forming a crystal layer of the low-resistance material.

### Effects of Invention

According to an embodiment of the present disclosure, a method of forming a film of a low-resistance material such as Ru, W, Mo, Co, and Rh on a semiconductor substrate film may obtain an amorphous-like film quality using a physical vapor deposition (PVD) method for a TiN layer, thereby increasing the grain size of Ru or the like and improving crystallinity. In addition, the method may perform an after-bias treatment on the TiN layer and adjust an appropriate radio frequency (RF) bias and time to improve the roughness of the TiN layer, thereby optimally suppressing void generation and improving crystallinity. Therefore, the method may ultimately control resistivity and crystallinity.

In addition, the method may deposit a Ru layer on the TiN layer in two steps (2 steps) and control nucleation in a first step (1^{st} step) regardless of deposition conditions of a second step (2^{nd} step) to increase the grain size and reduce the resistivity simultaneously.

Further, the method may adjust TiN film formation conditions (e.g., direct current (DC) voltage, RF voltage, Ar, N₂ flow rate, pressure, etc.) to optimally adjust an after-bias effect, thereby ultimately providing a semiconductor substrate film with an improved void and reduced resistivity and controlling the resistivity and crystallinity of the semiconductor substrate film through PVD without using chemical vapor deposition (CVD), atomic layer deposition (ALD), or the like.

The effects of the present disclosure are not limited to the ones described above but are construed as including all effects that may be inferable from the configurations and features described in the following description or claims of the present disclosure.

### BRIEF DESCRIPTION OF DRAWINGS

FIG. 1 is a diagram illustrating a TiN and Ru deposition process according to an embodiment of the present disclosure.

FIG. 2 is a diagram illustrating a process for forming a TiN film.

FIG. 3 is a diagram illustrating an after-bias and a process for forming a Ru film.

FIG. 4A is a diagram illustrating a result that Ru crystallinity is randomized, a grain size is decreased, and resistivity is increased, by instability of a TiN surface, TIN crystallization, and roughness of the TiN surface, when Ru (30 nm) is deposited without separate treatment after TiN (4 nm) is deposited.

FIG. 4B is a diagram illustrating a result that roughness and resistivity are improved when Ru (30 nm) is deposited after TiN (4 nm) is deposited as a film at a high pressure (1 to 40 pascal (Pa)) and a low temperature (100° C. or less) and an after-bias treatment is performed.

FIG. 5 is a diagram illustrating a result of measuring changes in resistivity of a Ru layer in which Ru is deposited in two steps (2 steps) under the same conditions after an after-bias treatment is performed under different conditions (e.g., RF power and time).

FIG. 6 is a diagram illustrating a result showing changes in grain size and resistivity obtained by depositing a Ru layer in a single step (1 step) with each direct current (DC) power (0.5 kilowatts (kW), 2 KW, and 4 kW), and a result showing a grain size and resistivity obtained by depositing a second layer (2^{nd} layer) of a Ru layer with a DC power of 2 KW after depositing a first layer (1^{st} layer) of the Ru layer with a DC power of 0.5 kW.

FIG. 7A shows a result of measuring a grain size and a resistivity value (10.79 μΩcm) after depositing a Ru layer (30 nm) on SiO₂ in a single step (1 step).

FIG. 7B shows a result of measuring a grain size and a resistivity value (10.50 μΩcm) after depositing a Ru layer (26 nm/4 nm) on SiO₂ in two steps (2 steps).

FIG. 7C shows a result of measuring a grain size, the number of grains, and a resistivity value (12.77 μΩcm) after depositing a Ru layer on TiN (4 nm) in a single step (1 step) without an after-bias treatment after TiN (4 nm) is deposited on SiO₂.

FIG. 7D shows a result of measuring a grain size, the number of grains, and a resistivity value (11.67 μΩcm) after depositing a Ru layer on TiN (4 nm) in a single step (1 step) with an after-bias treatment after TiN (4 nm) is deposited on SiO₂.

FIG. 7E shows a result of measuring a grain size, the number of grains, and a resistivity value (12.15 μΩcm) after depositing a Ru layer on TiN (4 nm) in two steps (2 steps) without an after-bias treatment after TiN (4 nm) is deposited on SiO₂.

FIG. 7F shows a result of measuring a grain size, the number of grains, and a resistivity value (11.08 μΩcm) after depositing a Ru layer on TiN (4 nm) in two steps (2 steps) with an after-bias treatment after TiN (4 nm) is deposited on SiO₂.

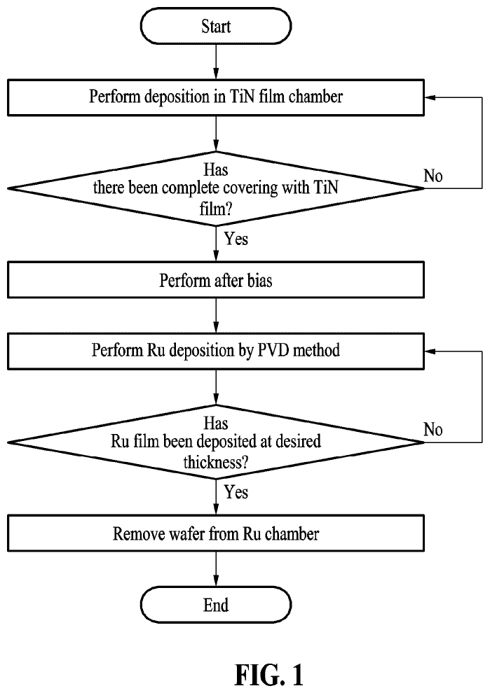

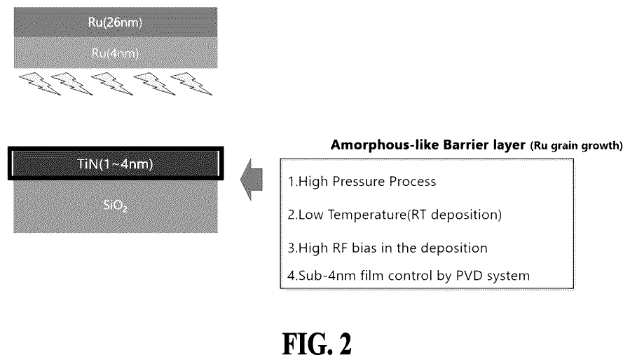

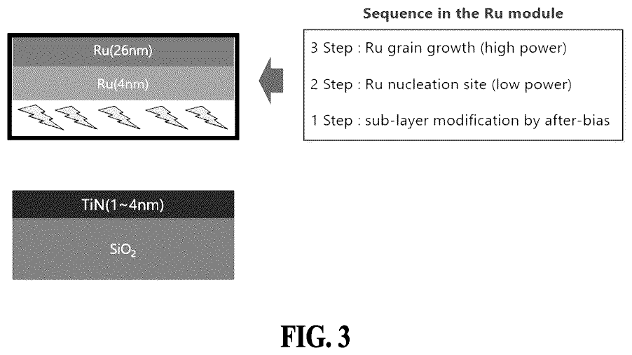

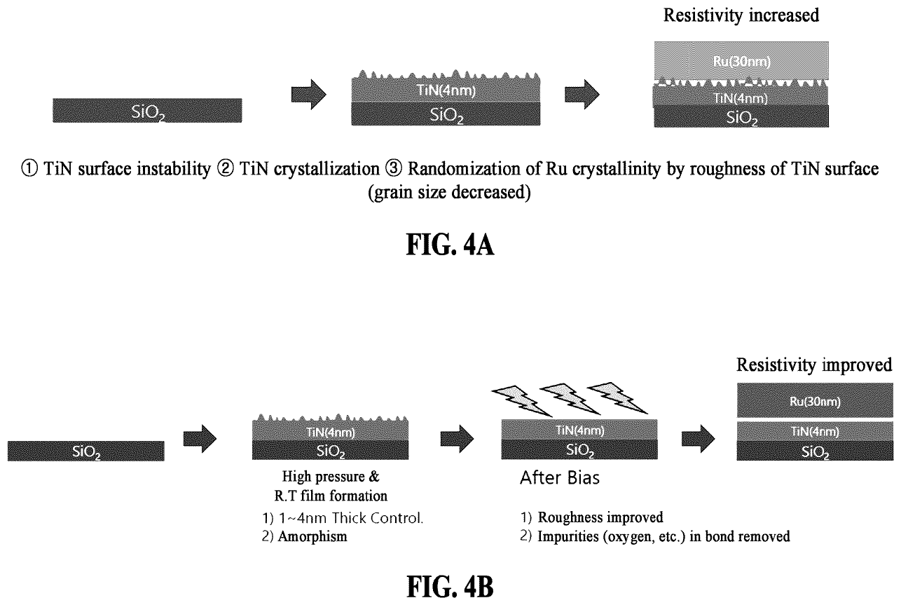

### BEST MODE FOR CARRYING OUT INVENTION

Hereinafter, example embodiments will be described in detail with reference to the accompanying drawings. However, various alterations and modifications may be made to the embodiments. The embodiments are not intended to limit the scope of claims of the present disclosure. The embodiments should be understood to include all changes, equivalents, and replacements within the idea and the technical scope of the disclosure.

The terminology used herein is for the purpose of describing particular embodiments only and is not intended to be limiting. The singular forms “a,” “an,” and “the” are intended to include the plural forms as well, unless the context clearly indicates otherwise. It will be further understood that the terms “comprises/comprising” and/or “includes/including,” when used herein, specify the presence of stated features, integers, steps, operations, elements, and/or components, but do not preclude the presence or addition of one or more other features, integers, steps, operations, elements, components and/or groups thereof.

Unless otherwise defined, all terms including technical and scientific terms used herein have the same meaning as commonly understood by one of ordinary skill in the art to which the embodiments of the present disclosure pertain. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

When describing the embodiments with reference to the accompanying drawings, like reference numerals refer to like components and a repeated description related thereto will be omitted. In the description of example embodiments, detailed description of well-known related structures or functions will be omitted when it is deemed that such description will cause ambiguous interpretation of the present disclosure.

According to an embodiment of the present disclosure, provided is a low-resistance material film formation method of forming a film on a semiconductor substrate using physical vapor deposition (PVD), the method including:
step (a) of depositing a barrier layer on a SiO₂ wafer using magnetron sputtering at a pressure of 1 to 40 pascal (Pa) and at a low temperature (100° C. or lower);
step (b) of, after the barrier layer is deposited, modifying the surface of the barrier layer by applying a radio frequency (RF) bias in an argon (Ar) gas atmosphere without applying a direct current (DC) power; and
step (c) of depositing a low-resistance material on the barrier layer using magnetron sputtering,
wherein the low-resistance material is at least one selected from the group consisting of tungsten (W), ruthenium (Ru), molybdenum (Mo), cobalt (Co), and rhodium (Rh).

The barrier layer formed through step (a) may be formed of not only titanium nitride (TiN), but also tantalum nitride (TaN) or silicon nitride (SiNₓ, where x>0), and the thickness of the barrier layer may be preferably 4 nanometers (nm) or less.

However, when the thickness exceeds 4 nm, as the resistivity of a low-resistance material such as Ru increases during the formation of a Ru/TiN film, there may be problems of signal delay and voltage drop and may also be a problem of degrading device performance.

The depositing of TiN or the like in the magnetron sputtering in step (a) may be performed under various deposition conditions, but the magnetron sputtering may be performed under the conditions of a high pressure and a low temperature (100° C. or less). A typical PVD process may be generally performed under the conditions of a pressure of 0.1 to 0.9 Pa, whereas the depositing according to the present disclosure may be performed at a high pressure of 1 to 40 Pa.

In addition, an after-bias effect may be exhibited differently depending on the film formation conditions for TiN or the like, and the best result (i.e., low resistivity) may be achieved from amorphous TiN under optimized film formation conditions. Thus, the film formation conditions for TiN may be optimal with a DC power of 10 to 30 kilowatts (KW), an RF power of 200 watts (W) or less, an Ar/N₂ ratio of 1/10 or less, a pressure of 1 to 40 Pa, and a low temperature (100° C. or less).

In addition, for adhesion and barrier, a low-resistance material such as Ru may be deposited on top of the SiO₂ wafer, along with a lower film such as TiN, and in this case, a Ru/TiN structure may increase resistivity.

To solve such a problem, the method according to an embodiment of the present disclosure may apply the RF bias in the Ar gas atmosphere before depositing the low-resistance material, after depositing the barrier layer in step (a), and may perform after-bias to modify the TiN surface.

The after-bias of step (b) may be performed to reduce the resistivity of a semiconductor substrate on which the low-resistance material is finally formed, which may improve the roughness of the surface of an unstable TiN layer that may exist by a typical method without after-bias, and remove impurities (e.g., oxygen, etc.) in a bond to increase a grain size of the deposited low-resistance material (Ru, Mo, W, Co, Rh, etc.) and reduce a void, thereby improving the resistivity.

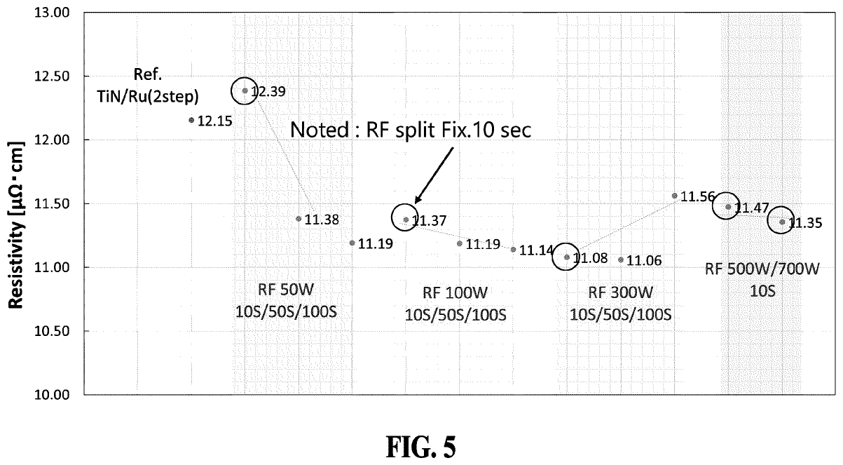

In addition, as shown in FIG. 5, it may be verified that adjusting an RF power and time in step (b) may finally adjust the resistivity. In addition, applying the RF bias of 50 to 300 W for 10 to 100 seconds, preferably of 100 to 300 W for 10 to 100 seconds, more preferably of 100 to 300 W for 10 to 60 seconds, or particularly preferably of 300 W for 10 to 50 seconds may significantly reduce the resistivity compared to the typical method, increase the grain size, and reduce a void.

According to an embodiment of the present invention, after performing the after-bias in step (b), the low-resistance material such as Ru, W, Mo, Co, and Rh may be deposited using magnetron sputtering, and the depositing may be continuously performed until the low-resistance material is deposited to have a desired thickness (step c).

In this case, the deposited thickness of the low-resistance material in step (c) may be 10 to 30 nm, and when it is deposited to have the desired thickness, the wafer may be removed from a chamber, and the low-resistance material film formation method may then be completed.

In addition, as described above, step (c) may be performed as single-step (1 step) deposition, or as two-step (2 step) deposition including a first step (1^{st} step) of forming a nucleation layer that is a seed layer and a second step (2^{nd} step) of forming a crystal layer to form a double layer.

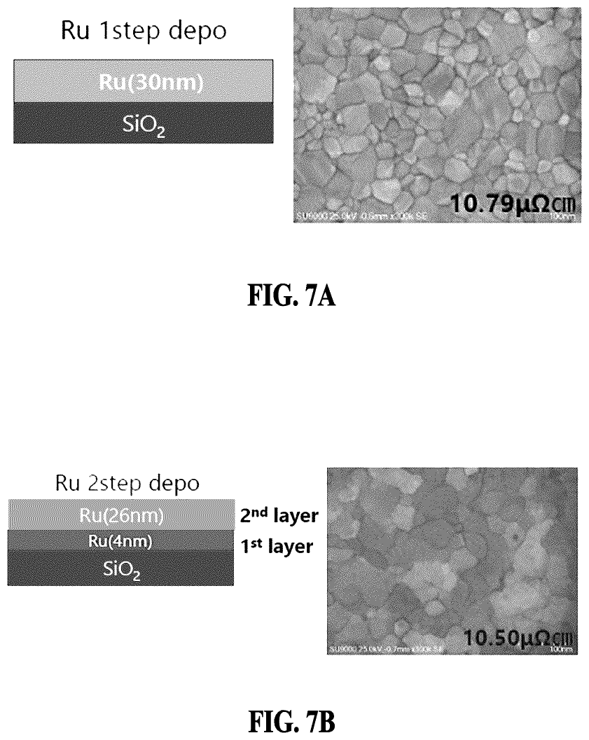

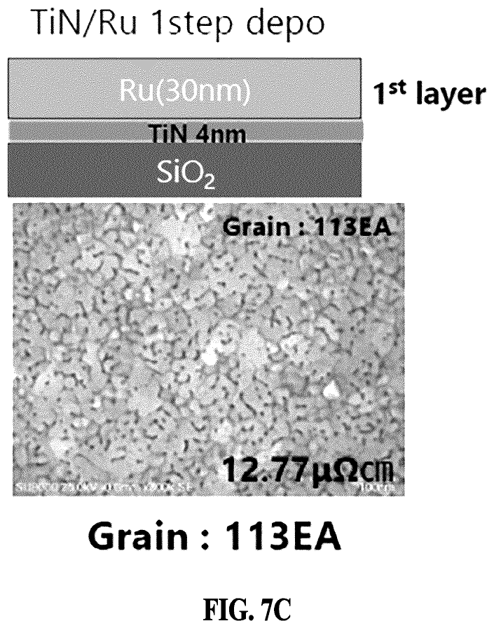

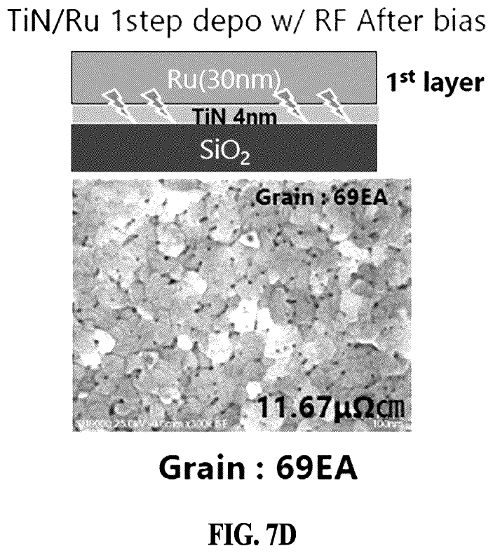

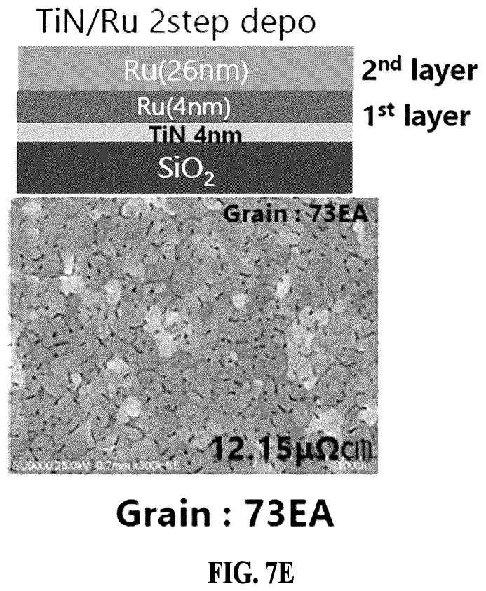

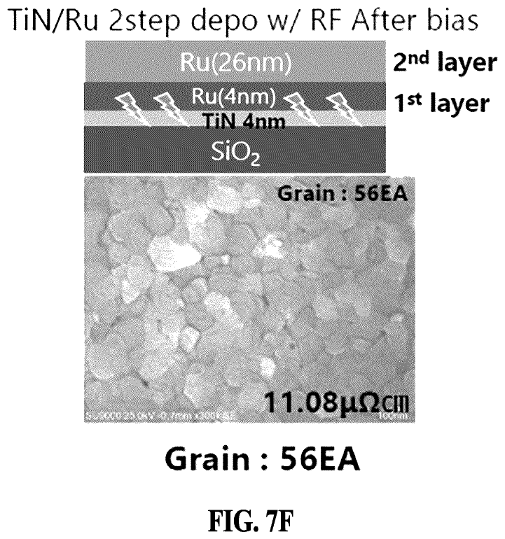

In this case, as shown in FIG. 7, it may be verified that cases shown in FIGS. 7E and 7F in which the low-resistance material (e.g., Ru) is formed as a double layer have a larger grain size, a fewer number of grains, and a smaller resistivity than those in cases shown in FIGS. 7C and 7D in which the low-resistance material is deposited through the single-step deposition, and the two-step deposition for forming a low-resistance material as a double layer may thus be more desirable than the single-step deposition. In this case, the number of grains was calculated by directly counting the number of grains in a certain portion (region) of the same size in respective scanning electron microscope (SEM) images.

In addition, controlling the nucleation by changing the operating conditions of the first step may reduce the resistivity regardless of the deposition conditions of the second step, and may also secure the resistivity of the same level as that obtained in the case of performing the single-step with the same DC power as in the step of forming the nucleation layer even though a high DC power than that applied in the step of forming the nucleation layer is applied in the step of forming the crystal layer and may thereby reduce a film formation time and distribution.

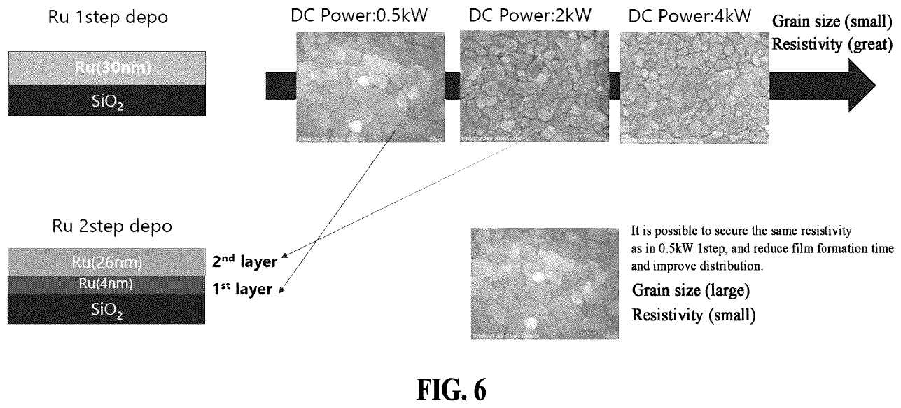

According to an embodiment, for example, when the Ru layer is deposited using DC power of 0.5 kW, 2 kW, and 4 kW in the single step (1 step), it may be verified that, as the DC power increases (see FIG. 6), the grain size decreases and the resistivity increases, and it may be verified that the grain size obtained when the DC power of 0.5 kW is used in the single step is almost the same as the grain size obtained when the DC power of 0.5 kW is used in the first step and the DC power of 2 kW is used in the second step (see FIG. 6).

Also, when the single-step (1 step) deposition is performed to form a film of a low-resistance material, the film formation conditions for the low-resistance material may include a DC power of 2 to 8 KW and an RF power of 50 W. In this case, when the DC power is lower than 2 kW, the film formation time may be increased, which may adversely affect mass production and degrade a film formation distribution. Also, when the DC power exceeds 8 KW, the grain size may be formed to be extremely small, and a resistivity value may be increased.

In addition, in the case of forming a film of a low-resistance material as a double layer by the two-step (2 step) film formation including the first step (1^{st} step) of forming a nucleation layer that is a seed layer and the second step (2^{nd} step) of forming a crystal layer, the DC power may be 0.3 to 1 kW for the first-step film formation, and the RF power may not be applied in this case. Also, in this case, when the DC power is lower than 0.3 kW, discharge may be difficult, and when the DC power exceeds 1 kW, the resistivity may be increased. Also, when the DC power is lower than 2 kW during the second-step film formation, the film formation time may be increased, which may adversely affect mass production and degrade the film formation distribution. Thus, the DC power of 2 to 10 kW may be desirable, and the RF power may be 50 W in this case.

In addition, the thickness of the nucleation layer (or the seed layer) may be preferably 4 nm or more because nucleation does not occur well when it is less than 4 nm, and a sum of the thicknesses of the nucleation layer and the thickness of the crystal layer may be preferably 10 to 30 nm. Because the thicker the nucleation layer formed with low power, the larger the grain size, which may improve the resistivity, there may be no upper limit in the thickness of the nucleation layer. In terms of mass production, forming the nucleation layer to be thick may require a great period of time for a film formation process, and thus 4 nm may be desirable as the thickness of the nucleation layer.

A semiconductor substrate on which a barrier layer such as TiN and a low-resistance material such as Ru, W, Mo, Co, or Rh are deposited by the method described herein may be used in a next-generation wiring structure as semiconductor devices have become finer in size, and may be, in particular, suitable for use for micropatterns with a pitch of less than 28 nm.

Hereinafter, the present disclosure will be described in more detail with examples. The following examples are described for the purpose of illustrating the present disclosure and are thus not provided to limit the scope of the present disclosure.

### EXAMPLES

### 1) TiN Deposition Method

Film formation was performed based on a PVD system using experimental equipment called ENTRON-EX. TiN and Ru films were formed in different process chambers, and a SiO₂ substrate was used as a substrate.

The substrate was transferred to a TiN chamber via a load lock chamber to be fixed, and power was applied to ESC and Ar/N₂ gas was fed to the chamber for a substrate temperature suitable for the film formation. DC was applied to a target part for discharge in the chamber, and RF was applied to the substrate stage part so that the deposition material moved from the target toward the substrate to form a film. In this case, RF plays a role in controlling the film quality and distribution by pulling ions toward the stage, and the TiN film formation conditions are as follows:
DC: 10 kW-30 kW;
RF: 200 W or less;
Ar/N₂ ratio: 1/10 or less;
Pressure: 1 to 40 Pa (high pressure); and
Temperature: low temperature (100° C. or below)

### 2) After-Bias Treatment Method

For an after-bias treatment, the substrate was moved to a Ru chamber after the TiN deposition was completed. Ar gas was fed to the chamber, RF bias was applied to the stage, and Ar ions were attracted to the substrate to be processed there. In this case, the after-bias conditions are as follows:
DC: 0 KW;
Ar: 170 sccm;
RF: 300 W; and
Time and temperature: 10 sec, high temperature of 200° C. or higher

### 3) Low-Resistance Material (Ru) Deposition Method

### Single-Step (1 Step) Film Formation Method

After the after-bias treatment, to deposit a Ru film on the TiN film obtained through the after-bias treatment in the same Ru chamber, Ru was deposited under film formation conditions including DC power of 2 kW, RF power of 50 W, Ar flow rate of 170 sccm, 470° C., and 65 seconds. As a result, a Ru film consisting of a single layer with a thickness of 30 nm was obtained.

### Two-Step (2 Steps) Film Formation Method

Similar to the single-step film formation described above, after the after-bias treatment, a 30 nm Ru film was deposited on the TiN film obtained through the after-bias treatment in the same Ru chamber. In this case, such a Ru film formation was performed by sequentially applying a first step under a low power condition and a second step under a high power condition, and the operating conditions and the film thicknesses corresponding to the respective steps are as follows:
Step 1: DC 0.5 KW, RF 0 W, Ar 170 sccm, 76 sec, 470° C., 4 nm (film thickness)
Step 2: DC 2 KW, RF 50 W, Ar 170 sccm, 56 sec, 470° C., 26 nm (film thickness)

As the grain size increases, the resistivity may be improved. The grain size may tend to increase further when the low power is applied. However, in terms of mass production, time is also important, and it is thus necessary to shorten the time by high-power film formation. Thus, the film formation is performed through two steps as described above.

That is, the large grain size may be obtained even with the high power applied in the second step by the effect of the grain size in the first step of Ru film formation. As a result, the resistivity and mass productivity may be partially improved.

After the Ru film formation, the wafer returned to Foup through a transfer chamber, and the experiment was then finished.

While the embodiments are described with reference to drawings, it will be apparent to one of ordinary skill in the art that various alterations and modifications in form and details may be made in these embodiments without departing from the spirit and scope of the claims and their equivalents. For example, suitable results may be achieved if the described techniques are performed in a different order and/or if described components are combined in a different manner and/or replaced or supplemented by other components or their equivalents.

Therefore, other implementations, other embodiments, and equivalents to the claims are also within the scope of the following claims.

1. A method of forming a film of a low-resistance material on a semiconductor substrate using physical vapor deposition (PVD), the method comprising:
step (a) of depositing a barrier layer on a SiO₂ wafer using low-temperature magnetron sputtering at a pressure of 1 to 40 pascal (Pa);
step (b) of modifying, after the barrier layer is deposited, the surface of the barrier layer by applying a radio frequency (RF) bias in an argon (Ar) gas atmosphere without applying direct current (DC) power; and
step (c) of depositing a low-resistance material on the barrier layer using magnetron sputtering,
wherein the low-resistance material is at least one selected from the group consisting of tungsten (W), ruthenium (Ru), molybdenum (Mo), cobalt (Co), and rhodium (Rh).

2. The method of claim 1, wherein the barrier layer is at least one selected from the group consisting of titanium nitride (TiN), tantalum nitride (TaN), and silicon nitride (SiNₓ, where x>0).

3. The method of claim 1, wherein the thickness of the barrier layer is 4 nanometers (nm) or less.

4. The method of claim 1, wherein the barrier layer is a TiN layer, and operating conditions for performing the magnetron sputtering in step (a) comprise DC of 10 kilowatts (kW) to 30 kW, RF of 200 watts (W) or less, an Ar/N₂ ratio of 1/10 or less, and a pressure of 1 to 40 Pa.

5. The method of claim 1, wherein step (b) comprises:
applying the RF bias of 100 to 300 W for 10 to 60 seconds.

6. The method of claim 1, wherein step (b) comprises:
applying the RF bias of 300 W for 10 seconds.

7. The method of claim 1, wherein a deposited thickness in step (c) is 10 to 30 nm.

8. The method of claim 1, wherein step (c) comprises:
forming a nucleation layer (seed layer) of the low-resistance material; and
forming a crystal layer of the low-resistance material.

9. The method of claim 8, wherein the thickness of the nucleation layer (seed layer) is 4 nm or more.

10. The method of claim 8, wherein the forming of the crystal layer comprises:
applying DC power higher than that used for the forming of the nucleation layer.

11. The method of claim 8, wherein RF in the forming of the nucleation layer is 0 W.

12. The method of claim 9, wherein a sum of the thickness of the nucleation layer (seed layer) and the thickness of the crystal layer is 10 to 30 nm.

13. The method of claim 1 or 8, wherein the low-resistance material is ruthenium (Ru).

14. The method of claim 1, wherein the semiconductor substrate on which a film of the barrier layer and the low-resistance material is formed is used for a fine pattern with a pitch of less than 28 nm.
